(19) United States
(12) Patent Application Publication
(10) Pub. No.: US 2011/0073887 A1
(43) Pub. Date: Mar. 31, 2011

(54) OPTOELECTRONIC DEVICES HAVING A DIRECT-BAND-GAP BASE AND AN INDIRECT-BAND-GAP EMITTER

(75) Inventors: MARK W. WANLASS, Golden, CO (US); Angelo Mascarenhas, Lakewood, CO (US)

(73) Assignee: ALLIANCE FOR SUSTAINABLE ENERGY, LLC, Golden, CO (US)

(21) Appl. No.: 12/566,769

(22) Filed: Sep. 25, 2009

(51) Int. Cl. H01L 33/00; H01L 29/20

(52) U.S. Cl. 257/94; 438/47; 257/201; 257/E33.019; 257/E33.005; 257/E29.089

(57) ABSTRACT

Optoelectronic devices, junctions and methods of fabricating a device or junction where the emitter layer is of an indirect-band-gap material and the base layer is of a direct-band-gap material. The device or junction may have, among other structures and layers, a base layer of a first semiconductor material having a first conductivity type and further having a direct band gap and an emitter layer forming a junction with the base layer. In this embodiment, the emitter layer may be of a second semiconductor material having a second conductivity type and further having an indirect band gap. The optoelectronic device may have the semiconductor material of the emitter layer substantially lattice mismatched with the semiconductor material of the base layer in bulk form. Alternatively, the emitter layer may be substantially lattice matched with the base layer.

### CONTRACTUAL ORIGIN

The United States Government has rights in this invention under Contract No. DE-AC36-08GO28308 between the United States Department of Energy and the Alliance for Sustainable Energy, LLC, the manager and operator of the National Renewable Energy Laboratory.

### BACKGROUND

Semiconductor materials have a characteristic band gap. The band gap is defined as an energy range in a solid material where no electron states exist. For semiconductor materials, the band gap generally refers to the energy difference, measured in electron volts, between the top, or highest energy state, of the valence band and the bottom, or lowest energy state, of the conduction band of the material. Thus, the band gap is the amount of energy to move an outer shell electron from its orbit about an atomic nucleus to a free state.

The band gap of a semiconductor material may be described as being of one of two types; a direct band gap or an indirect band gap. For any semiconductor material, the minimal-energy state in the conduction band and the maximal-energy state in the valence band may each be characterized by a k-vector in the Brillouin zone. As shown in FIG. 1, if the k-vectors are coincident, the material is described as having a direct band gap. As illustrated in FIG. 2, if the k-vectors are separated, the material is described as having an indirect band gap.

The nature of a semiconductor material band gap, whether direct or indirect, directly influences the physical properties of the material and thus the behavior of the semiconductor material in an optoelectronic device. In particular, any interaction among electrons, electron holes, photons, phonons and other particles satisfies conservation of energy and crystal momentum. For example, one important process which occurs within the semiconductor material of an optoelectronic device is radiative recombination. Radiative recombination occurs where an electron in the conduction band of a material fills a level in the valence band, releasing excess energy as a photon. Another important process is absorption which occurs when a photon excites an electron in the valence band to fill a higher energy level in the conduction band. Since the k-vectors of direct-band-gap materials match and crystal momentum is not affected by a transition, these processes are far more likely to occur in a direct-band-gap semiconductor than in an indirect-band-gap semiconductor. Because energy and crystal momentum are conserved, radiative recombination or absorption occurs in an indirect-band-gap material if the process also involves the absorption or emission of a phonon. In this case, as illustrated in FIG. 2, the phonon momentum equals the difference between the electron and hole momentum. The involvement of a phonon makes the process of radiative recombination or absorption much less likely to occur in an indirect-band-gap material, thus, an indirect-band-gap semiconductor is relatively transparent to light.

The above noted physical phenomenons directly impact the suitability of any particular semiconductor material for use in an optoelectronic device. For example, known varieties of photovoltaic cells (PV cells) can be made from either indirect-band-gap materials or direct-band-gap materials. Crystalline silicon is an indirect-band-gap semiconductor. Many PV cells have at least one junction between a p-type conductivity layer and an n-type conductivity layer. The PV cell creates a potential when photogenerated charge carriers drift or diffuse across the junction. The relative transparency of the silicon may be considered somewhat advantageous since light can readily pass through the overlying, sunward, emitter layer which forms the first part of the junction to the underlying base layer which defines the other part of the junction, deeper within the cell. On the other hand, the relative transparency of the silicon or other indirect-band-gap material minimizes photon absorption as described above, such that a silicon solar cell is relatively thick to function effectively. If a silicon PV cell or a PV cell made from another indirect-band-gap material were made relatively thinner most of the incident light simply passes through the cell without being absorber, and thus the energy associated with the light may be lost.

Other types of PV cells are commonly made of direct-band-gap materials such as cadmium telluride (CdTe) or copper indium gallium (di)selenide (CIGS). These direct-band-gap materials absorb light quite well and thus can be fabricated into a PV cell much thinner than a silicon solar cell. However, the use of a direct-band-gap material in the emitter layer, facing the sun, necessarily results in substantially less light energy passing through the emitter to the underlying base layer.

Another obstacle decreasing the efficiency of PV cells fabricated from direct-band-gap semiconductor materials is that typical direct-band-gap materials, such as III-V compound semiconductor alloys, exhibit a high surface recombination velocity which leads to substantial losses of photo-generated minority carriers at the emitter surface away from the junction.

The typical solution to the surface recombination problem inherent in a direct-band-gap emitter layer is to passivate the emitter by applying a “window” material of a higher band gap over the emitter layer to lower the surface recombination velocity and thus lower associated photocurrent losses. The option of applying such a window layer however, is not always readily implemented for a selected emitter semiconductor material. Furthermore, optical absorption in the window material itself results in losses since the window also has a free surface with a potentially high recombination velocity.

In summary, PV cells constructed of indirect-band-gap materials such as silicon exhibit reduced quantum efficiency because of the relative transparency of the silicon material itself. Conversely, PV cells constructed from direct-band-gap materials may suffer from reduced quantum efficiency because of the high recombination velocity at the surface of the indirect-band-gap material, the necessity of supplemental “window” layers to overcome this problem and the relative opacity of direct-band-gap materials which limits the amount of light which may be passed through the emitter layer to the base layer.

Similar obstacles may be noted in optoelectronic devices which emit light, for example light emitting diodes (LEDs). Because radiative recombination is slow in indirect-band-gap materials, LEDs are almost always made of direct-band-gap materials. However, the emission of photons from the surface of a direct-band-gap emitter to the environment is relatively lower than the emission of photons within the device. This reduction in quantum efficiency may be caused in part by the relative opacity of the direct-band-gap material used to form the n-p or p-n junction within the device.

The embodiments disclosed herein are intended to overcome one or more of the limitations described above. The foregoing examples of the related art and limitations related therewith are intended to be illustrative and not exclusive. Other limitations of the related art will become apparent to those of skill in the art upon a reading of the specification and a study of the drawings.

### SUMMARY

The following embodiments and aspects thereof are described and illustrated in conjunction with systems, tools and methods which are meant to be exemplary and illustrative, not limiting in scope. In various embodiments, one or more of the above-described problems have been reduced or eliminated, while other embodiments are directed to other improvements.

One embodiment is an optoelectronic device having, among other structures and layers, a base layer of a first semiconductor material having a first conductivity type and further having a direct-band-gap and an emitter layer forming a junction with the base layer. In this embodiment, the emitter layer may be of a second semiconductor material having a second conductivity type and further having an indirect band gap. The optoelectronic device may have the semiconductor material of the emitter layer substantially lattice mismatched with the semiconductor material of the base layer in bulk form. Alternatively, the emitter layer may be substantially lattice matched with the base layer.

In an embodiment of the optoelectronic device where the emitter layer is substantially lattice mismatched with the base, the emitter layer may be deposited, formed or grown to have a thickness of less than a critical thickness of the second semiconductor material to thus produce a coherent interface with the base layer. In an embodiment where the emitter layer is substantially lattice matched with the base, the emitter layer may be intentionally disordered by decreasing the order parameter of the alloy, so as to facilitate the crossover from direct to indirect band gap.

Alternative embodiments include a junction as described above and a method of fabricating an optoelectronic device or junction as described above.

In addition to the exemplary aspects and embodiments described above, further aspects and embodiments will become apparent by reference to the drawings and by study of the following descriptions.

### BRIEF DESCRIPTION OF THE DRAWINGS

Exemplary embodiments are illustrated in referenced figures of the drawings. It is intended that the embodiments and figures disclosed herein are to be considered illustrative rather than limiting.

FIG. 1 is a graphic representation of the energy and momentum relationship of a direct-band-gap material.

FIG. 2 is a graphic representation of the energy and momentum relationship of an indirect-band-gap material.

FIG. 3 is a schematic diagram of a device having a junction as described herein.

### DETAILED DESCRIPTION

Unless otherwise indicated, all numbers expressing quantities of ingredients, dimensions, reaction conditions and so forth used in the specification and claims are to be understood as being modified in all instances by the term “about”.

In this application and the claims, the use of the singular includes the plural unless specifically stated otherwise. In addition, use of “or” means “and/or” unless stated otherwise. Moreover, the use of the term “including”, as well as other forms, such as “includes” and “included”, is not limiting. Also, terms such as “element” or “component” encompass both elements and components comprising one unit and elements and components that comprise more than one unit unless specifically stated otherwise. A material may be described herein as being “single crystal.” Single crystal very specifically means an ingot, wafer or epilayer that is truly a single crystal, with no grain boundaries. “Crystalline” is a more general term for a substantially crystalline material which can have grain boundaries. Crystalline shall be understood to mean substantially crystalline, and having sufficiently well developed crystal structure that one skilled in the art refers to the material as being crystalline. The terms single crystal and crystalline do not mean absolutely defect free. Both types of material may have defects and/or dislocations. Certain abbreviations may be made herein with respect to the description of semiconductor alloys. These abbreviations shall not be construed as limiting the scope of the disclosure or claims. For example, the form “InGaAlN” is a common abbreviation to improve readability in technical manuscripts. Abbreviated forms such as “InGaAlN” are defined as equivalent to an expanded form, for example; “InₓGa_{y}Al_{1-x-y}N”.

As used herein, epitaxy, epitaxial and epitaxially are generally defined as relating to the process where one crystalline substance is grown or deposited on another crystalline substance. As used herein in relation to epitaxial processes, “grown and grow” are synonymous with “deposited and deposit” and may be formed by any suitable process.

The various embodiments disclosed herein include optoelectronic devices having a p-n or n-p junction as described in detail below. As used herein, a “junction” can be one of a p-n or n-p junction. As used herein, an “optoelectronic” device is any semiconductor device which emits, absorbs, detects or controls light. Optoelectronic devices include, but are not limited to, photoelectric or photovoltaic devices such as photodiodes, including solar cells and related devices, phototransistors, photomultipliers or integrated optical circuit elements. Optoelectronic devices also encompass photoconductivity devices such as photo resistors, photoconductive camera tubes or charged-coupled imaging devices. Optoelectronic devices also include stimulated emission devices such as laser diodes or LEDs.

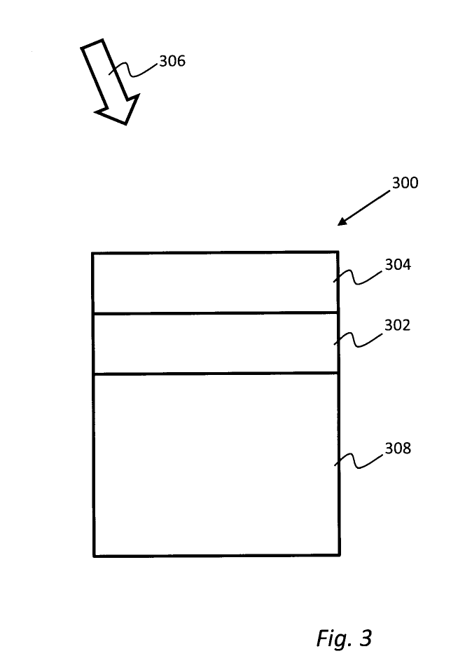

The various optoelectronic devices disclosed herein include at least one p-n or n-p junction which may be a homojunction or heterojunction. The junction includes a base layer and an emitter layer in physical contact with, associated with or in electrical contact with, the base layer. For example, as schematically illustrated in FIG. 3, an optoelectronic device 300 may have a base layer 302 associated with an emitter layer 304. One type of optoelectronic device which may benefit from the structures disclosed herein is a solar cell. With respect to a solar cell, the “emitter” or the “emitter layer” is the portion of a p-n or n-p junction which faces a source of light, for example the sun as represented by arrow 306 on FIG. 3. Therefore, used herein, the “base” or “base layer” 302 is the opposite portion of the junction away from the source of light in the case of an absorption device such as a solar cell. The base layer 302 is typically associated with a substrate 308 which may provide mechanical strength, reflectivity a growth template or other advantageous properties to a device.

The term “emitter” originated with junction transistors (which have an emitter, a base and a collector, i.e. two back to back p-n junctions), because in such junction transistor, carriers that are emitted from the “emitter” pass thru the base and are collected by the collector. Normally for a conventional diode having one p-n junction, the doped regions of the junction are not referred to as emitter or base. However, historically in the PV field, it is customary to refer to the bottom lying region of the junction as the base, and this region was, in the original cell designs, much thicker than the emitter. Note however that for solar cells, photogenerated carriers that are in fact emitted from the base and flow up to the emitter. This is accepted nomenclature for PV devices, even though the word “emitter” is technically a misnomer.

It may be noted that optoelectronic emission devices such as LEDs or VCSEL lasers are not typically described as having emitter and base layers. With respect to consistency within this disclosure however, the opposite sides or regions of a p-n or n-p junction in an LED, diode laser or similar device are described herein as an emitter and base. In the case of an emission device, either the emitter or base can be fabricated to be on the “top” of the device, toward the emission environment.

The base layer 302 and emitter layer 304 may be of opposite conductivity types. In particular, one of either the base or the emitter layer may be selected, prepared or doped to have p-type conductivity and the other layer may have n-type conductivity. It is important to note that the base 302 may be of either p or n conductivity type provided that the emitter 304 is of the opposite conductivity type.

In all embodiments the semiconductor material of the base layer may be selected, prepared or created to have a direct band gap. In addition, the semiconductor material of the emitter layer may be selected, prepared or created to have an indirect band gap. Accordingly, absorptive optoelectronic devices as disclosed herein, for example a PV cell, may have enhanced internal quantum efficiency because of the relative transparency of the emitter layer thereby reducing potential losses due to surface recombination in combination with the highly absorptive base layer. Furthermore, the use of an indirect-band-gap material in the emitter layer provides for absorptive devices which function at a relatively high quantum efficiency without the need for passivating window layers to reduce surface recombination losses. In addition, an emissive device as disclosed herein, for example an LED may have enhanced emissive external quantum efficiency because of the relatively transparent emitter layer between the junction and the outside environment.

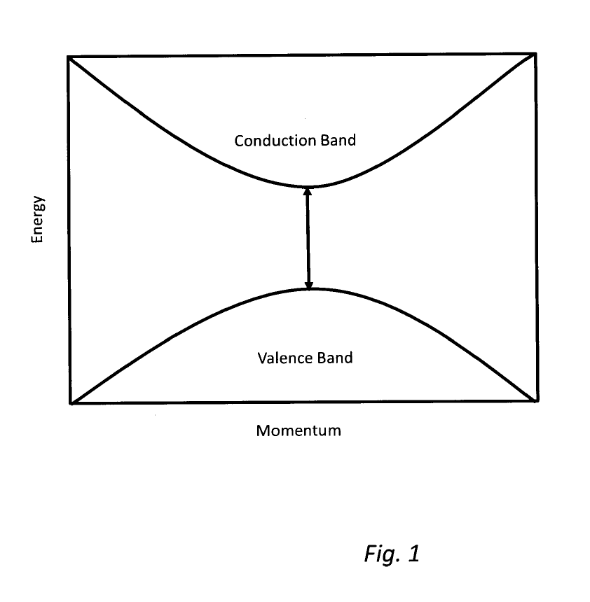

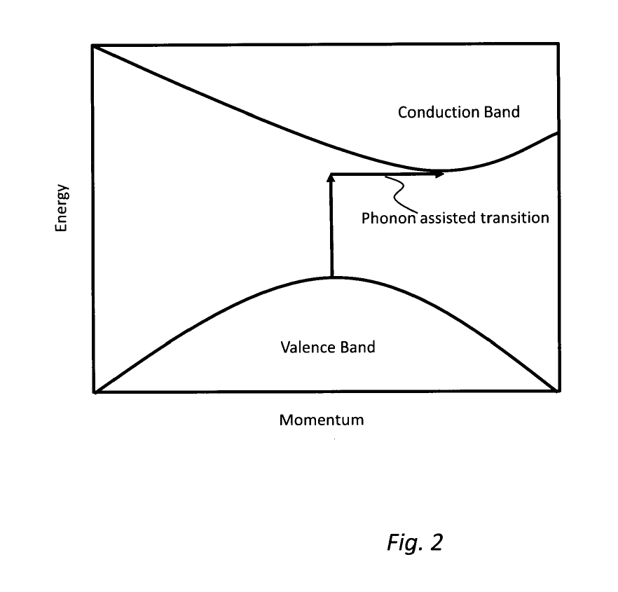

As discussed in detail above and illustrated in FIG. 1, a direct-band-gap material is one where an electron can shift between the lowest energy state in the conduction band to the highest energy state in the valence band without a change in crystal momentum. Direct-band-gap materials absorb light strongly. On the contrary, an indirect-band-gap material such as is illustrated in FIG. 2 is relatively transparent. In an indirect-band-gap material, an electron cannot shift between the lowest energy state of the conduction band to the highest energy state of the valence band without a change in momentum. Thus, for radiative recombination or absorption to occur in an indirect-band-gap material, a phonon must be absorbed or emitted. Accordingly, the various embodiments of optoelectronic device enclosed herein feature a relatively transparent indirect-band-gap emitter and a direct-band-gap base layer where light is absorbed very rapidly with depth. In addition, the photogenerated charge carriers in the base layer may be collected extremely efficiently by the n-p or p-n junction between the emitter and base layer.

The devices disclosed herein which feature a direct-band-gap base and indirect-band-gap emitter may be contrasted with known devices that feature a semiconductor body defining a p-n or n-p junction which is of either an entirely indirect-band-gap type or direct-band-gap type. For example the junction of a crystalline silicon PV cell is entirely composed of an indirect-band-gap material; silicon, and the junctions of known thin film solar cells or LEDs are composed entirely of direct-band-gap materials.

It is important to note that the band gap of compound semiconductor materials, in particular, group III-V semiconductor alloys or group II-VI semiconductor alloys is a function of the selected constituent element concentrations which make up the alloy. Thus, many semiconductor alloys, for example, the III-V semiconductor alloy GaInP can be a direct-band-gap material if the ratio of In to Ga is relatively high in the alloy. On the contrary, GaInP may be an indirect-band-gap material if the ratio of Ga to In is relatively high in the alloy. Typically, binary semiconductor materials such as GaP or InP are either indirect or direct-band-gap materials depending upon the crystal structure of the binary alloy and other factors. Accordingly, ternary and quaternary alloys may be prepared to have either a direct band gap or indirect band gap depending upon the specific ratio of elements selected to prepare the alloy. Ternary or quaternary alloys may be grown or formed by known epitaxial methods including but not limited to vapor-phase epitaxy (VPE), liquid-phase epitaxy (LPE), molecular beam epitaxy (MBE), metal organic chemical vapor deposition (MOCVD) and others.

As described above, the embodiments disclosed herein feature a base layer 302 of a semiconductor material having a direct band gap and an emitter layer 304 of a semiconductor material having an indirect band gap. Typically, but not exclusively, as a device is fabricated epitaxially or otherwise, the base layer may be applied to or associated with a substrate and the emitter layer may be applied to or associated with the base layer. Other preparation or growth strategies are within the scope of the present disclosure. In addition, actual devices may have multiple stacked emitter and base layers plus any number of intervening, underlying or overlying layers. Although single base and emitter layers forming a single junction are, for purposes of clarity, discussed extensively herein, it is critical to note that the disclosed and claimed structures may be implemented in devices having any number of active or inactive layers.

Generally, the emitter layer may be identified as falling into broad groups according to the relationship of the crystalline structure of the emitter layer to the crystalline structure of the base layer, which in turn relates to the crystalline structure of the alloys selected to form each layer. In the first case, the semiconductor selected for the emitter layer may be substantially lattice mismatched with the semiconductor of the base layer in the bulk form of the respective materials. Alternatively, the material of the emitter layer may be substantially lattice matched with the material of the base layer. Lattice matching occurs when the crystal matrix of each layer has a substantially equivalent lattice constant, and one layer is epitaxially grown on the other. Thus, in a lattice matched embodiment the atoms of the emitter layer may, for example, be grown or deposited upon the atoms of the base layer with the atoms of the base layer serving as a growth template for the overlying emitter layer, thus minimizing crystal dislocations or defects in the emitter layer.

As described above, within a range of alloys, the existence of a specific ternary or quaternary semiconductor alloy as a direct or indirect-band-gap material is a function of the ratio of constituent elements in the alloy. The ratio of the constituent elements in the alloy also affects the lattice constant of the resulting crystalline structure. The observation that the ratio of constituent elements in a semiconductor alloy affects both the band gap of the material and the lattice constant of the material highlights one difficulty inherent in the preparation of a junction featuring an indirect-band-gap emitter and direct-band-gap base; it is likely that semiconductor alloys prepared to have desired band gap properties may be highly lattice mismatched in bulk form.

The problem of a lattice mismatched emitter and base combination can be overcome by pseudomorphically growing the emitter layer to a thickness which is less than a critical thickness of the selected emitter semiconductor alloy. In particular, a relatively thin mismatched epitaxial emitter layer can be grown without excessive dislocation formation on an underlying base layer under specific conditions which maintain a coherent interface between the two layers. The term “coherent interface” is defined herein as a layer interface where the emitter epilayer takes on the same, or substantially the same, lattice constant as the underlying base layer, e.g., by elastic deformation, thus providing a layer interface which is functionally lattice matched, even though the respective lattice constants for each of the materials in bulk form may be substantially different.

The critical thickness as a function of lattice mismatch may vary from alloy composition to composition. However, the “critical thickness” of a strained epilayer is defined as that thickness below which the biaxial strain between the mismatched layers is accommodated by uniform elastic deformation of the epilayer such that it assumes the lattice constant of the underlying base semiconductor layer. When the critical thickness is surpassed, the strain between the mismatched layers is sufficient to favor the nucleation of misfit dislocation at the layer interface. In this instance, the interface between the layers is no longer coherent due to the formation of dislocations in the epilayer. While the maximum thickness defined by such critical thickness may vary, it is believed the critical thickness for most material combinations may be in the range of approximately 10-1000 Angstrom. The actual determination of the critical thickness of a particular emitter material deposited on a particular base material depends on a number of different parameters related to both the material the conditions under which it is being synthesized. Such parameters include the elastic constants relating to the particular materials and other factors including those related to the strain energy and the energy to nucleate misfit dislocations.

As described above, group III-V semiconductor alloys may be selected to produce a junction or a device having at least one junction which features an indirect-band-gap emitter and direct-band-gap base. Also as described above, the constituent element ratios of ternary or quaternary semiconductor alloys may be selected such that different compositions within the same family of alloys are either an indirect or direct-band-gap material. At a specific alloy composition for many selected ternary or quaternary semiconductor alloys, a transition point may be identified where the alloy becomes a direct-band-gap material or an indirect-band-gap material. For group III-V semiconductor alloys the actual band gap of the transition point varies with the alloy selected. It may be advantageous, particularly in the case of a junction prepared with a single alloy type which is formulated in the emitter to have indirect band gap properties and in the base to have direct band gap properties to select or prepare the alloys such that the emitter and base semiconductor materials are unambiguously indirect or direct-band-gap materials respectively.

For example, it may be advantageous to select the emitter material such that it has a band gap at least 70 meV above the direct-indirect crossover point where the semiconductor alloy of the emitter becomes substantially an indirect-band-gap material. Similarly, it may be advantageous to select or prepare the base semiconductor alloy to have a band gap at least 70 meV below the direct-indirect crossover point where selected base semiconductor alloy becomes substantially a direct-band-gap material. In alternative embodiments, the emitter band gap material may be selected or prepared to have a band gap at least 80 meV, 90 meV, 100 meV, 110 meV, 120 meV, 130 meV, 140 meV, 150 meV, 160 meV, 170 meV, 180 meV, 190 meV or 200 meV above the direct-indirect crossover at which the selected semiconductor alloy becomes substantially an indirect-band-gap material. Similarly, it may be advantageous to select or prepare the base semiconductor alloy to have a band gap at least 80 meV, 90 meV, 100 meV, 110 meV, 120 meV, 130 meV, 140 meV, 150 meV, 160 meV, 170 meV, 180 meV, 190 meV or 200 meV below the direct-indirect crossover where selected semiconductor alloy becomes substantially a direct-band-gap material.

Specific pairs of group III-V semiconductor alloys which may be used to prepare optoelectronic devices as described above having a substantially lattice mismatched indirect-band-gap emitter layer and a direct-band-gap base layer include, but are not limited to the following pairs: base: GaInP, emitter: GaInP; base: GaInP, emitter: AlGaInAsP; base: GaAsP, emitter: GaAsP; base: GaAsP, emitter: AlGaInAsP; base: AlInAs, emitter: AlInAs and base: (Al)GaSb, emitter AlGaSb.

As described above, a substantially lattice mismatched emitter layer, if grown to a thickness of less than a critical thickness to maintain a coherent interface with the base layer may be strained. Typically, the lattice constant of a selected type of crystalline semiconductor alloy may decrease as the ratio of constituent elements within the alloy is adjusted to increase the band gap and ultimately prepare an indirect-band-gap material. Thus, typically, an indirect-band-gap emitter layer grown or deposited on a direct-band-gap base layer may be under tensile strain. For an n-type emitter, tensile strain may lower the valence band effective mass thereby reducing hole dark current. Accordingly, improved conversion efficiency may be achieved in devices with an n-type emitter which is prepared to have a coherent interface with a p-type base as described above.

Alternatively, the indirect-band-gap emitter layer may be prepared from an alloy which is substantially lattice matched with the base layer. Such an optoelectronic device may include emitter and base layers which are composed of group III-V semiconductor alloys or group II-VI semiconductor alloys. The base may be selected or prepared to be both a direct-band-gap material, and to have a band gap which is at least 80 meV, 90 meV, 100 meV, 110 meV, 120 meV, 140, meV, 160 meV, 170 meV, 180 meV, 190 meV, 200 meV or other selected value lower than the band gap of the indirect-band-gap emitter. Representative base and emitter pairs include, but are not limited to the following: base: GaAs, emitter: AlGaInP; base: GaAs, emitter: AlGaAs; base: InP, emitter: AlGaAsSb; base: InAs, emitter: AlGaAsSb; base GaInAs, emitter AlInAs; base: GaInP, emitter: AlGaInP; and base: GaAsP, emitter: AlGaAsP.

In the case of a lattice matched embodiment, the semiconductor material of the base layer may be selected to be of an n-conductivity type and the semiconductor material of an emitter layer may be selected to be of a p-conductivity type. This particular conductivity configuration may provide specific advantages because the atoms of the emitter layer may be intentionally disordered by decreasing the order parameter of the alloy, so as to facilitate the crossover from direct to indirect band gap.

Other embodiments include methods of forming, fabricating or growing any type of optoelectronic device where an emitter layer of a semiconductor material having an indirect band gap is grown, associated with, deposited or applied to a base layer of a semiconductor material having a direct band gap. The emitter layer may be grown or formed by known epitaxial methods including but not limited to vapor-phase epitaxy (VPE), liquid-phase epitaxy (LPE), molecular beam epitaxy (MBE), metal organic chemical vapor deposition (MOCVD) and others.

The emitter layer may be grown from a material which in bulk form is substantially lattice mismatched with the base layer, in which case, it may be advantageous to grow the emitter layer to thickness less than a critical thickness to produce a coherent interface with a base layer. Alternatively, the junction or the junction of the optoelectronic device may be prepared where the emitter layer is grown substantially lattice matched to the base layer with or without the intentional disordering of the atoms of the emitter layer to facilitate the crossover from direct to indirect band gap.

The disclosed methods may be implemented to prepare an absorptive device such as a PV cell which functions at a relatively high internal quantum efficiency without the need for passivating window layers to reduce surface recombination losses. The disclosed methods may be implemented to prepare an emissive device such as an LED which functions at a relatively high emissive external quantum efficiency because of the relative transparency of the emitter layer.

Although single p-n or n-p junctions have been discussed above for simplicity, the scope of the present disclosure includes optoelectronic devices having multiple junctions, each having a p and n layer as described above in a string, stack or combination of strings and stacks. The scope of the present disclosure also encompasses devices having any number of other active or inactive layers.

Various embodiments of the disclosure may also include permutations of the various elements recited in the claims as if each dependent claim was a multiple dependent claim incorporating the limitations of each of the preceding dependent claims as well as the independent claims. Such permutations are expressly within the scope of this disclosure.

While the invention has been particularly shown and described with reference to a number of embodiments, it is understood by those skilled in the art that changes in the form and details may be made to the various embodiments disclosed herein without departing from the spirit and scope of the invention and that the various embodiments disclosed herein are not intended to act as limitations on the scope of the claims. All references cited herein are incorporated in their entirety by reference.

The description of the present invention has been presented for purposes of illustration and description, but is not intended to be exhaustive or limiting of the invention to the form disclosed. The scope of the present invention is limited only by the scope of the following claims. Many modifications and variations will be apparent to those of ordinary skill in the art. The embodiment described and shown in the figures was chosen and described in order to best explain the principles of the invention, the practical application, and to enable others of ordinary skill in the art to understand the invention for various embodiments with various modifications as are suited to the particular use contemplated.

While a number of exemplary aspects and embodiments have been discussed above, those of skill in the art will recognize certain modifications, permutations, additions and sub combinations thereof. It is therefore intended that the following appended claims and claims hereafter introduced are interpreted to include all such modifications, permutations, additions and sub-combinations as are within their true spirit and scope.

What is claimed is:

1. An optoelectronic device comprising:
a base layer comprising a first semiconductor material having a first conductivity type and further having a direct band gap; and
an emitter layer forming a junction with the base layer, wherein the emitter layer comprises a second semiconductor material having a second conductivity type and further having an indirect band gap.

2. The optoelectronic device of claim 1 wherein the second semiconductor material of the emitter layer is substantially lattice mismatched with the first semiconductor material of the base layer in bulk form.

3. The optoelectronic device of claim 2 further comprising an emitter layer thickness of less than a critical thickness of the second semiconductor material to produce a coherent interface with the base layer.

4. The optoelectronic device of claim 3 wherein the emitter layer thickness is less than or equal to 1 μm.

5. The optoelectronic device of claim 3 wherein the first semiconductor material comprises a first Group III-V semiconductor alloy and the second semiconductor material comprises a second Group III-V semiconductor alloy.

6. The optoelectronic device of claim 5 comprising:
the first Group III-V semiconductor alloy having a band gap at least about 70 meV below a direct-indirect crossover where the first semiconductor alloy becomes substantially a direct-band-gap material; and
the second Group III-V semiconductor alloy having a band gap at least about 70 meV above a direct-indirect crossover where the second semiconductor alloy becomes substantially an indirect-band-gap material.

7. The optoelectronic device of claim 5 wherein the base layer and emitter layer comprise a pair of Group III-V semiconductor alloys selected from:
base: GaInP, emitter: GaInP;
base: GaInP, emitter: AlGaInAsP;
base: GaAsP, emitter: GaAsP;
base: GaAsP, emitter: AlGaInAsP;
base: AlInAs, emitter: AlInAs; and
base: (Al)GaSb, emitter AlGaSb.

8. The optoelectronic device of claim 2 further comprising:
the first semiconductor material of the base layer being of a p conductivity type; and
the second semiconductor material of the emitter layer being of an n conductivity type.

9. The optoelectronic device of claim 8 further comprising the substantially lattice mismatched emitter layer being under tensile strain.

10. The optoelectronic device of claim 1 wherein the second semiconductor material of the emitter layer is substantially lattice matched with the first semiconductor material of the base layer.

11. The optoelectronic device of claim 10 wherein the first semiconductor material comprises a first Group III-V semiconductor alloy and the second semiconductor material comprises a second Group III-V semiconductor alloy.

12. The optoelectronic device of claim 11 further comprising the first Group III-V semiconductor alloy having a band gap at least about 80 meV lower than the band gap of the second Group III-V semiconductor alloy.

13. The optoelectronic device of claim 11 wherein the base layer and emitter layer comprise a pair of Group III-V semiconductor alloys selected from:
A. base: GaAs, emitter: AlGaInP;
B. base: GaAs, emitter: AlGaAs;
C. base: InP, emitter: AlGaAsSb;
D. base: InAs, emitter: AlGaAsSb;
E. base GaInAs, emitter AlInAs;
F. base: GaInP, emitter: AlGaInP; and
G. base: GaAsP, emitter: AlGaAsP.

14. The optoelectronic device of claim 10 further comprising:
the first semiconductor material of the base layer being of an n conductivity type; and
the second semiconductor material of the emitter layer being of a p conductivity type.

15. The optoelectronic device of claim 10 further comprising the second semiconductor material of the substantially lattice matched emitter layer being disordered to provide a selected indirect-band-gap.

16. A method of forming an optoelectronic device comprising:
providing a base layer comprising a first semiconductor material having a first conductivity type and further having a direct band gap; and
associating an emitter layer with the semiconductor base layer, the emitter comprising a second semiconductor material having a second conductivity type and further having an indirect band gap.

17. The method of forming an optoelectronic device of claim 16 wherein the second semiconductor material is substantially lattice mismatched with the first semiconductor material in bulk form.

18. The method of forming an optoelectronic device of claim 17 further comprising growing the emitter layer to a thickness less than a critical thickness of the second semiconductor material to produce a coherent interface with the base layer.

19. The method of forming an optoelectronic device of claim 18 further comprising growing the emitter layer under tensile strain.

20. The method of forming a optoelectronic device of claim 17 further comprising providing a first semiconductor material for the base layer having a p type conductivity.

21. The method of forming an optoelectronic device of claim 17 wherein:
the first semiconductor material is a Group III-V semiconductor alloy having a band gap at least about 70 meV below a direct-indirect crossover where the first semiconductor alloy becomes a direct-band-gap material; and
the second semiconductor material is a Group III-V semiconductor alloy having a band gap at least about 70 meV above a direct-indirect crossover where the second semiconductor alloy becomes an indirect-band-gap material.

22. The method of forming an optoelectronic device of claim 16 wherein the emitter layer is grown substantially lattice matched with the base layer

23. The method of forming a optoelectronic device of claim 22 wherein the first semiconductor material is a Group III-V semiconductor alloy having a band gap at least about 80 meV below a band gap of the second semiconductor material.

24. The method of forming an optoelectronic device of claim 22 further comprising disordering the atoms of the second semiconductor material.

25. A junction comprising:
a base layer comprising a first semiconductor material having a first conductivity type and further having a direct band gap; and
an emitter layer in contact with the base layer, the emitter layer comprising a second semiconductor material having a second conductivity type and further having an indirect band gap.
